(19) United States
(12) Patent Application Publication
(10) Pub. No.: US 2026/0129918 A1
(43) Pub. Date: May 7, 2026

(54) TRANSISTOR STRUCTURE FOR VERTICAL FLASH MEMORY, VERTICAL FLASH MEMORY AND METHOD OF FORMING SAME

(71) Applicant: IMEC VZW, Leuven (BE)

(72) Inventors: Devin Verreck, Pellenberg (BE); Sana Rachidi, Leuven (BE); Maarten Rosmeulen, De Pinte (BE)

(21) Appl. No.: 19/379,547

(22) Filed: Nov. 4, 2025

(30) Foreign Application Priority Data
Nov. 5, 2024 (EP) 24210894.2

(51) Int. Cl. H10D 30/68; H10B 41/27; H10B 41/30; H10D 30/01; H10D 62/17

(52) U.S. Cl. CPC H10D 30/689; H10B 41/27; H10B 41/30; H10D 30/0411; H10D 62/235

(57) ABSTRACT

In one aspect, a transistor structure for a vertical NAND flash memory device is provided. The transistor structure includes a semiconductor channel layer, a first auxiliary layer and a second auxiliary layer arranged on opposite sides of the semiconductor channel layer along a first axis, and each of the first auxiliary layer and the second auxiliary layer comprises a first material having a first relative permittivity greater than 1 and less than 3.9. The transistor structure further includes a first dielectric layer arranged above the semiconductor channel layer, the first auxiliary layer and the first auxiliary layer along a second axis that is perpendicular to the first axis; a charge storage layer arranged on the first dielectric layer; a second dielectric layer arranged on the charge storage layer; and a gate layer arranged on the second dielectric layer.

### CROSS-REFERENCE TO RELATED APPLICATIONS

This application claims foreign priority to European Patent Application No. EP 24210894.2, filed Nov. 5, 2024, the entire content of which is incorporated by reference herein in its entirety.

### BACKGROUND

### Field

The disclosed technology relates to a transistor structure for a vertical NAND flash memory device, a method of processing the transistor structure, and a vertical NAND flash memory device including one or more of the transistor structures.

### Description of the Related Technology

A flash memory is a type of non-volatile memory that can be electrically programmed and erased. A NAND flash is a special type of flash memory, in which the individual memory cells are connected in series in the form of a NAND gate. A NAND flash with a three-dimensional (3D) architecture, e.g., a NAND flash with memory cells that are arranged vertically, is generally referred to as 3D NAND or vertical NAND.

NAND flash memory can store information in a non-volatile way in the form of charge carriers (e.g., electrons and/or holes) in a charge trap layer or in a floating gate that is part of a flash cell transistor. The concentration of stored charge carriers can correspond to the bits of information stored in the memory, and can be read by a resulting threshold voltage shift of the flash cell transistor. Quantum tunneling may be utilized to change the concentration of the charge carriers, thereby writing or erasing information into/from the memory.

The dimensions of the flash cells of the vertical NAND flash memories have been scaled down over previous technology generations to increase bit densities. The production technology has transitioned from planar devices to vertical, 3D structures, in which the memory string can include a cylindrical memory hole along which the flash cells are stacked, also called gate-all-around (GAA) strings. These strings can be fabricated by first depositing a stack of alternating layers, followed by etching a memory hole and then filling the memory hole with the memory and channel layers.

Such 3D structures allow increasing the bit density by adding more cells to the strings, rather than scaling the cell dimensions. However, the etching process becomes more challenging as the aspect ratio of the memory holes increases, thereby ultimately limiting the number of cells on a string.

In the 3D trench cell architecture, the memory operation may be further degraded as the vertical cell pitch is scaled, similar to the degradation observed in GAA structures. Combined with the flat cell geometry, this scaling can lead to poor overall memory performance.

### SUMMARY OF CERTAIN INVENTIVE ASPECTS

It is thus an objective of the disclosed technology to provide a 3D trench NAND flash memory structure with improved performance, and an improved method of forming the memory structure. In particular, the above-mentioned disadvantages may be mitigated.

The objective and other advantages are achieved by the embodiments provided in the independent claims. Additional advantageous implementations are further defined in the dependent claims.

As described herein, the term “vertical NAND flash memory” refers to a 3D NAND flash memory structure. The disclosed technology is directed to a vertical NAND flash memory having a trench-type channel structure, and not to a GAA structure.

According to a first aspect, the disclosed technology relates to a transistor structure for a vertical NAND flash memory device. The transistor structure may comprise a semiconductor channel layer, a first auxiliary layer and a second auxiliary layer arranged on two opposite sides of the semiconductor channel layer along a first axis, wherein each of the first auxiliary layer and the second auxiliary layer comprises a first material having a first relative permittivity, the first relative permittivity being larger than 1 and lower than 3.9. The transistor structure may further comprise a first dielectric layer arranged above the semiconductor channel layer, the first auxiliary layer and the second auxiliary layer, along a second axis that is perpendicular to the first axis. Further, the transistor structure may comprise a charge storage layer arranged on the first dielectric layer, a second dielectric layer arranged on the charge storage layer, and a gate layer arranged on the second dielectric layer.

The first auxiliary layer and the second auxiliary layer at both sides of the semiconductor channel layer may generally function as “pockets” having a low relative permittivity, as will be discussed further below. The semiconductor channel may be referred to as a fin, which extends between the two auxiliary layers along the second axis, the fin being sandwiched along the first axis between the two auxiliary layers.

Each of the first dielectric material layer and the second dielectric material layer can be formed from a dielectric material, such as silicon oxide or silicon nitride.

In this disclosure, the terms “semiconductor channel layer,” “channel layer,” and “channel” may be used interchangeably.

The transistor structure according to the first aspect provides the advantage of inducing charge polarization at the interface between each pocket and the first dielectric layer, thereby locally increasing the electric field around the interface between the channel and the first dielectric layer, particularly near the corners of the channel. The corners of the semiconductor channel layer refer to two opposite sides of the channel (along the first axis) that are in direct contact with the first dielectric layer above the channel layer and the respective first or second auxiliary layer adjacent to the channel layer.

Further, when the transistor structure is used to form a vertical NAND flash memory, the aforementioned enhanced electric field at the corners of the channel can facilitate charge carrier injection during programming and erase of the vertical NAND flash memory.

The transistor structure may be a flash cell transistor or floating gate transistor. Thus, the first dielectric layer may be or may act as a tunnel oxide layer, the charge storage layer may be or may act as a floating gate, the second dielectric layer may be or may act as a blocking oxide layer, and the gate layer may be or may act as a control gate. Accordingly, these terms are used interchangeably in this disclosure. Thus, when a high voltage is applied to the control gate, charge carriers (e.g., electrons and/or holes) can tunnel from the channel to the tunnel oxide layer along the second axis, and remain there even when the control gate voltage is removed.

In an implementation form of the first aspect, the first auxiliary layer may partially extend into the first dielectric layer along the second axis. Additionally or alternatively, the second auxiliary layer may partially extend into the first dielectric layer along the second axis.

This is beneficial for enhancing the electric field at the interface between the first auxiliary layer (or first pocket) and the first dielectric layer, and/or at the interface between the second auxiliary layer (or second pocket) and the first dielectric layer.

In some embodiments, the first material may be or may comprise air. In this case, the first auxiliary layer and the second auxiliary layer may act as air-gaps at both sides of the semiconductor channel layer.

In some embodiments, the first material may comprise a porous material.

The porous material forming the pockets and the air in the case of the air-gaps may have the relative permittivity in a range between 1.0 and 3.9, for example, between 1.0 and 1.5, between 1.5 and 2.0, between 2.0 and 2.5, between 2.5 and 3.0, between 3.0 and 3.5, between 3.5 and 3.9, or a value in a range defined by any of these values.

In some embodiments, the first dielectric layer may comprise a second material having a second relative permittivity. The second relative permittivity is greater than the first relative permittivity.

Thus, the first auxiliary layer and the second auxiliary layer at both sides of the semiconductor channel may each have the first relative permittivity that is lower than the second relative permittivity of the first dielectric layer, e.g., tunnel oxide. The first material may have a low first permittivity.

This increases the electric field at the interface between the first auxiliary layer and the first dielectric layer, and the electric field at the interface between the second auxiliary layer and the first dielectric layer.

Such an enhanced electric field may attribute to charge polarization induced at the interface between the pocket and the tunnel oxide due to the difference in their respective relative permittivities. The stronger electric field in the tunnel oxide may increase the tunneling probability of charge carriers, therefore facilitating carrier injection from the channel into the tunnel oxide.

In some embodiments, a cross section of the semiconductor channel layer in a region below the first dielectric layer may have a rectangular, trapezoidal, or triangular shape.

This provides the advantage of further enhancing the electric field at the corners of the channel and in the vicinity of the interface between the channel and the tunnel oxide. Thereby, the injection of charge carriers from the channel into the tunnel oxide is further enhanced.

In some embodiments, the transistor structure may further comprise a first spacer layer arranged between the first auxiliary layer and the semiconductor channel layer along the first axis.

Additionally or alternatively, the transistor structure may further comprise a second spacer layer arranged between the semiconductor channel layer and the second auxiliary layer along the first axis.

This configuration facilitates easy integration in the fabrication process for vertical NAND flash memories, in which inter-channel spacer layers may be used to reduce crosstalk between the channels.

In some embodiments, the first spacer layer and/or the second spacer layer comprise a third material.

The third material has a third relative permittivity, and the third relative permittivity may be greater than the first relative permittivity and smaller than the second relative permittivity.

In some embodiments, each of the first spacer layer and the second spacer layer may be formed of silicon dioxide (SiO₂).

In some embodiments, the transistor structure may further comprise a source structure and a drain structure. The source structure may be arranged in a region adjacent to the first auxiliary layer, and the drain structure may be arranged in a region adjacent to the second auxiliary layer.

According to a second aspect, the disclosed technology relates to a vertical NAND flash memory device comprising one or more transistor structures according to the first aspect.

That is, the transistor structure according to the first aspect can be, or may serve as, a memory cell for the vertical NAND flash memory device.

By introducing the pockets or air-gaps adjacent to the string of channels with a reduced permittivity relative to that of the tunnel oxide, charge polarization may be induced at the interface between each pocket or air gap and the tunnel oxide, thereby locally enhancing the electric field around the corners of the channels. This can result in an enhanced charge carrier injection during programming and erase of the memory.

According to a third aspect, the disclosed technology relates to a method of fabricating a transistor structure for a vertical NAND flash memory. The method may comprises: forming a semiconductor channel layer; forming a first auxiliary layer and a second auxiliary layer on opposite sides of the semiconductor channel layer along a first axis, wherein each of the first auxiliary layer and the second auxiliary layer comprises a first material with a first relative permittivity, the first relative permittivity being larger than 1 and lower than 3.9; forming a first dielectric layer above the semiconductor channel layer, the first auxiliary layer and the second auxiliary layer, along a second axis perpendicular to the first axis; forming a charge storage layer on the first dielectric layer; forming a second dielectric layer on the charge storage; and forming a gate layer on the second dielectric layer.

Optionally, prior to forming the semiconductor channel layer, the method may further comprise a step of providing substrate. Then, the semiconductor channel layer may be formed above the substrate, and both the first and second auxiliary layers may be formed above the substrate and on opposite sides of the semiconductor channel layer along the first axis.

The method may further comprise a step of forming a source structure in a region adjacent to the first auxiliary layer along the first axis. Additionally or alternatively, the method may further comprise a step of forming a drain structure in a region adjacent to the second auxiliary layer along the first axis.

The semiconductor channel layer, and the first and second dielectric layers can be formed by using a suitable deposition technique, for example chemical vapor deposition (CVD), plasma enhanced chemical vapor deposition (PECVD), reduced pressure chemical vapor deposition (RPCVD), atomic layer deposition (ALD), or other deposition techniques.

In certain embodiments, the first auxiliary layer and the second auxiliary layer comprising air, e.g., the air-gaps, can be formed by deposition, subsequent thermal decomposition and out-diffusion of a polymer to create the air gaps. Prior processing the polymer, the method may include deposition of an oxide liner that has to be sufficiently thin to allow for the polymer out-diffusion. This can provide a stable structure, since when the method is employed to fabricate the vertical NAND flash memory according to the second aspect, the liner may be supported on two sides by the channel layers extending along a full length of a string of transistor structures according to the first aspect (e.g., a string of memory cells).

In other embodiments, when the first auxiliary layer and the second auxiliary layer comprise the porous material with low relative permittivity, the pockets can be formed with a method that does not rely on the polymer deposition and later out-diffusion as in the case for forming air-gaps. Thereby, the first auxiliary layer and the second auxiliary layer comprising the porous material can be formed in relatively simple manner.

### BRIEF DESCRIPTION OF THE DRAWINGS

The above described aspects and implementations are explained in the following description of embodiments with respect to the enclosed figures:

FIG. 1 schematically illustrates a transistor structure according to embodiments.

FIG. 2 schematically illustrates a transistor structure according to embodiments.

FIG. 3 schematically illustrates a transistor structure according to embodiments.

FIG. 4 schematically illustrates a transistor structure according to embodiments.

FIG. 5 schematically illustrates a transistor structure according to embodiments.

FIGS. 6a and 6b illustrate electric fields in transistor structures according to embodiments.

FIGS. 7a to 7d illustrate electric fields in transistor structures according to embodiments.

FIG. 8 shows examples of the first material according to embodiments.

FIG. 9 is a flowchart illustrating an example method of fabricating a transistor structure according to embodiments.

FIGS. 10a to 10h schematically show various intermediate or final structures formed in the course of performing an example method of fabricating a vertical NAND flash memory according to embodiments.

FIGS. 11a to 11f schematically show various intermediate or final structures formed in the course of performing an example method of fabricating a vertical NAND flash memory according to embodiments.

Same elements shown in the figures are labeled with the same reference numerals, and may be implemented likewise. The size of elements in the figures are not drawn to scale and may be different compared to an actual implementation in order to highlight details of the embodiments.

### DETAILED DESCRIPTION OF CERTAIN ILLUSTRATIVE EMBODIMENTS

Among other efforts, efforts to further increase the bit density have focused on scaling down the vertical cell pitch, which comprises the flash cell gate length and the inter-gate spacing. This, however, increases the interference between cells, and degrades the gate control over the carrier injection.

Alternatively, a 3D trench cell architecture has been developed for the vertical NAND flash memory. Instead of cylindrical holes, as in the conventional GAA structure, the memory strings in the 3D trench cell architecture are fabricated in elongated trenches, wherein each trench accommodates multiple strings in which the channels are separated with an insulating oxide material. This allows packing the strings very closely together, thereby increasing the bit density.

Transitioning to a 3D trench cell with scaled vertical pitch enables large bit densities, but also significantly degrades the memory operation of the cells. The flash cells in the trenches are flat, and therefore do not benefit from the so-called “curvature effect” of GAA cells. In a cylindrical GAA cell, the tunnel oxide has a smaller radius than the blocking oxide, which ensures a larger electric field in the tunnel oxide than in the blocking oxide for a given gate voltage. This enhances the injection of the charge carriers through the tunnel oxide relative to their escape through the blocking oxide, and therefore improves the memory operation. Further, since in the 3D trench cell architecture the memory stack is flat, the electric field is more evenly distributed over the tunnel and blocking oxides.

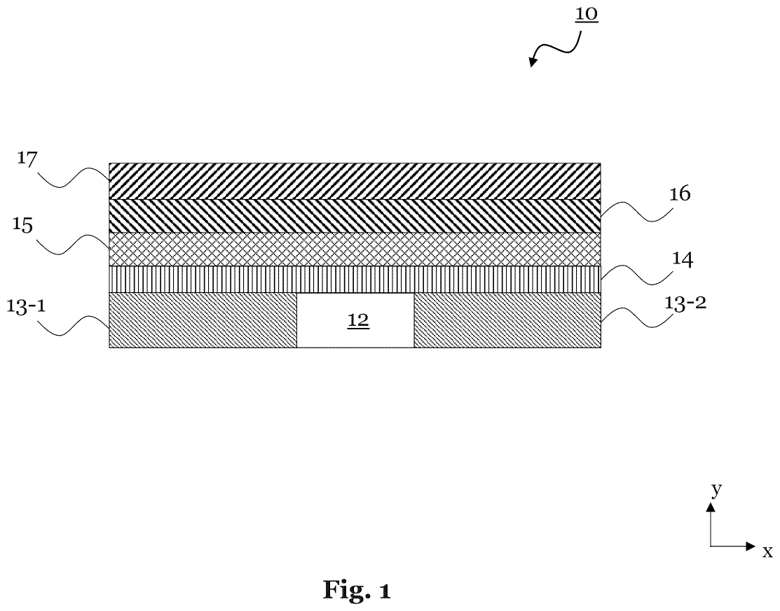

FIG. 1 schematically illustrates a transistor structure 10 according to an embodiment. In particular, FIG. 1 shows a cross-sectional view of the transistor structure 10 along an x-y plane in the schematic coordinate system shown in FIG. 1.

The transistor structure 10 may comprise a semiconductor channel layer 12, a first auxiliary layer 13-1 and a second auxiliary layer 13-2 that are arranged on opposite sides of the semiconductor channel layer 12 along a first axis, for example the x-axis in the schematic coordinate system shown in FIG. 1.

Each of the first auxiliary layer 13-1 and the second auxiliary layer 13-2 may comprise a first material. The first material may have a first relative permittivity ε_{r,1}, that is greater than 1 and less than 3.9. That is, 1<ε_{r,1}<3.9. In some embodiments, the first relative permittivity ε_{r,1} may be, for example, between 1.0 and 1.5, between 1.5 and 2.0, between 2.0 and 2.5, between 2.5 and 3.0, between 3.0 and 3.5, between 3.5 and 3.9, or a value in a range defined by any of these values.

The relative permittivity is also known as dielectric constant, which is a property of materials having a small dielectric constant relative to SiO₂ that are referred to as low-k materials. Thus, in this disclosure, the first material may also be referred to as first low-k material and, accordingly, each of the first auxiliary layer 13-1 and the second auxiliary layer 13-2 may comprise a first low-k material.

The first material may be, or may comprise, air, which may have the first relative permittivity ε_{r,1} of about 1.0.

In other embodiments, the first material may be, or may comprise, a porous material having the first relative permittivity between 1.0 and 3.9, as mentioned above. In some embodiments, the porous material may have the first relative permittivity between 1.0 and 1.5, between 1.5 and 2.0, between 2.0 and 2.5, between 2.5 and 3.0, between 3.0 and 3.5, between 3.5 and 3.9, or a value in a range defined by any of these values. The first material may be, or may comprise, a low-k porous material.

When the first material is air, each of the first auxiliary layer 13-1 and the second auxiliary layer 13-2 may be referred to as an air-gap. When the first material is the low-k porous material, each of the first auxiliary layer 13-1 and the second auxiliary layer 13-2 may be referred to as a pocket.

As shown schematically in FIG. 1, the first auxiliary layer 13-1, the semiconductor channel layer 12 and the second auxiliary layer 13-2 have a vertical dimension along the second axis that may be substantially equal to one another. For example, the vertical dimension may be a thickness or a height of the respective layer and, thus, the first auxiliary layer 13-1, the semiconductor channel layer 12 and the second auxiliary layer 13-2 may have the same thickness, e.g., the three layers may be aligned.

In the embodiment according to FIG. 1, the first auxiliary layer 13-1 and the semiconductor channel layer 12 may be arranged adjacent to each other along the first axis, and may be directly in contact with each other. The second auxiliary layer 13-2 and the semiconductor channel layer 12 may be arranged adjacent to each other along the first axis, and may be directly in contact with each other.

In other embodiments, the first auxiliary layer 13-1 and the semiconductor channel layer 12 may not be in direct contact with each other along the first axis. The second auxiliary layer 13-2 and the semiconductor channel layer 12 may not be in direct contact with each other along the first axis, as will be discussed further below.

Referring to FIG. 1 the transistor structure 10 may further comprise a first dielectric layer 14 arranged above the semiconductor channel layer 12, the first auxiliary layer 13-1 and the first auxiliary layer 13-1, along a second axis that is perpendicular to the first axis, for example the y-axis indicated in the schematic coordinate system shown in FIG. 1.

The transistor structure 10 may further comprise a charge storage layer 15 arranged on the first dielectric layer 14, a second dielectric layer 16 arranged on the charge storage layer 15, and a gate layer 17 arranged on the second dielectric layer 16.

That is, the first dielectric layer 14, the charge storage layer 15, the second dielectric layer 16 and the gate layer 17 are vertically arranged (along the y-axis) above the first auxiliary layer 13-1, the semiconductor channel layer 12 and the first auxiliary layer 13-2. In other embodiments, the first auxiliary layer 13-1, the semiconductor channel layer 12 and the first auxiliary layer 13-2 may be horizontally arranged (along the x-axis) with respect to each other.

As discussed above, the transistor structure 10 may be a flash cell transistor or a floating gate transistor. Thus, the first dielectric layer 14 may be or may act as a tunnel oxide layer, the charge storage layer 15 may be or may act as a floating gate, the second dielectric layer 16 may be or may act as a blocking oxide layer, and the gate layer 17 may be or may act as a control gate.

The first dielectric layer 14 may comprise a second material that has a second relative permittivity ε_{r,2}. The second relative permittivity ε_{r,2} may be greater than the first relative permittivity ε_{r,1}, ε_{r,1}<ε_{r,2}.

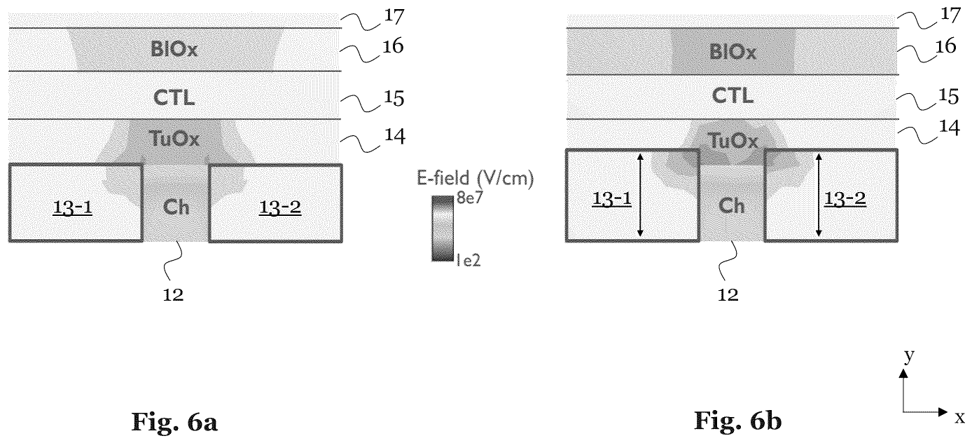

By introducing a pocket or an air-gap at both sides of the semiconductor channel layer 12 with a reduced permittivity relative to that of the first dielectric layer 14 (or tunnel oxide), charge polarization may be induced at an interface between each pocket/air-gap and the first dielectric layer. The charge polarization can locally enhance the electric field around the corners of the semiconductor channel layer 12, wherein the corners of the semiconductor channel layer 12 refer to the two opposite sides of the semiconductor channel layer 12 along the first axis that are in contact with the first dielectric layer 14 and that are in the vicinity of the two pockets/air-gaps. FIG. 6a illustrates simulations results for the electric field in the transistor structure 10 according to FIG. 1, showing the electric field enhancement at the corners of the semiconductor channel layer 12.

Thereby, when the transistor structure 10 is used as a memory cell in a vertical NAND flash memory device, the enhanced electric field can facilitate carrier injection during programming and erase of the memory device.

Moreover, the beneficial impact of the pockets or air gaps 13-1, 13-2 may be more prominent for small values of the first relative permittivity ε_{r,1}. That is, a larger difference between the second relative permittivity ε_{r,2} and the first permittivity ε_{r,1}, e.g., a larger difference between the relative permittivity of the first dielectric layer 14 and the relative permittivity of the first or second auxiliary layers 13-1, 13-2, may result in an further enhanced induced charge polarization for a given gate voltage and, hence, a larger electric field enhancement at the channel corners.

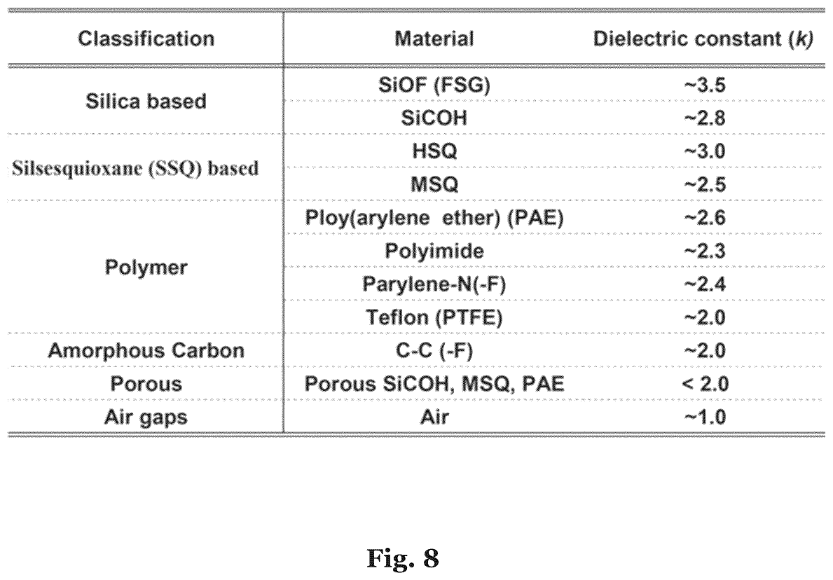

For example and not as a limitation, FIG. 8 shows exemplary first materials that can be comprised in the first auxiliary layer 13-1 and/or the second auxiliary layer 13-2 and a value of their corresponding first relative permittivity. In the figure, the term “dielectric constant” is used to refer to the relative permittivity.

Furthermore, introducing the pockets or air-gaps at both sides of the semiconductor channel layer 12, provides the additional advantage of reducing crosstalk with neighboring channels when one or more transistor structures 10 are used as memory cells in the vertical NAND flash memory device.

In the embodiment according to FIG. 1, a cross section of the semiconductor channel layer 12 in a region below the first dielectric layer 14 may have a rectangular, or substantially rectangular shape.

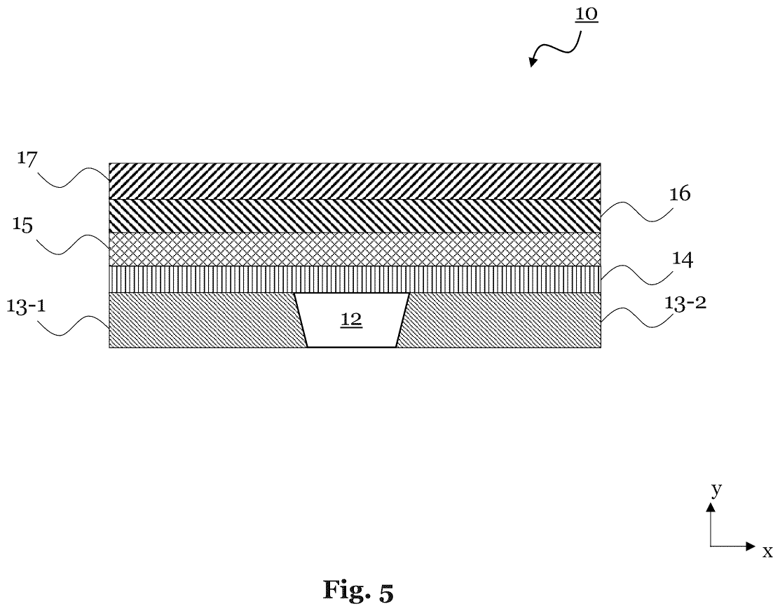

Alternatively, the cross section of the semiconductor channel layer 12 in the region below the first dielectric layer 14 may have other suitable shape, for example a trapezoidal or substantially trapezoidal shape, as shown in the embodiment according to FIG. 5, or a triangular shape.

By forming a non-rectangular-shaped interface between the semiconductor channel layer 12 and the first dielectric layer 14, the electric field at the interface can be further enhanced.

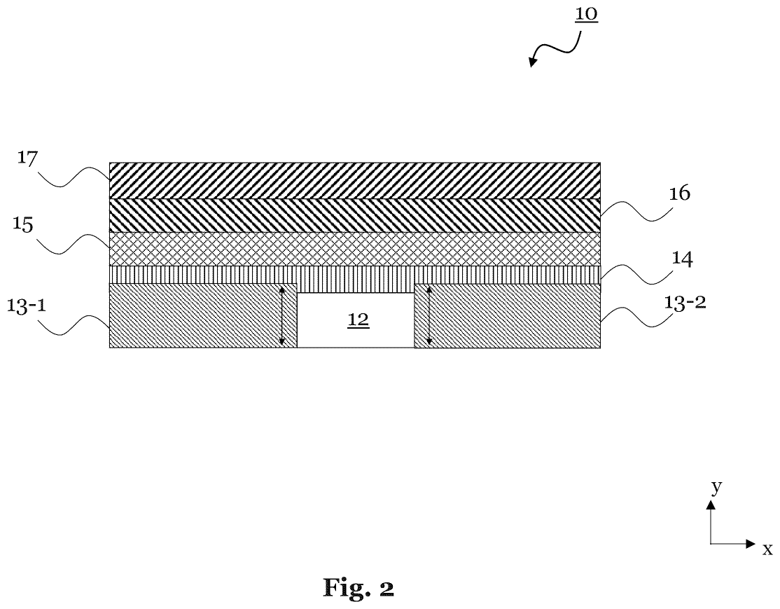

FIG. 2 schematically illustrates a transistor structure 10 according to an embodiment, which builds on the embodiment shown in FIG. 1. In particular, FIG. 2 shows a cross-sectional view of the transistor structure 10 along the x-y plane. Hereinafter, for brevity, only the differences between FIG. 2 and FIG. 1 are explained.

In the transistor structure 10 according to FIG. 2, the first auxiliary layer 13-1 may partially extend into the first dielectric layer 14 along the second axis, for example the y-axis.

Additionally or alternatively, the second auxiliary layer 13-2 may partially extend into the first dielectric layer 14 along the second axis, for example the y-axis.

This is beneficial, since such an extension may further enhance the electric field around the corners of the semiconductor channel layer 12, as shown in FIG. 6b.

The pockets or air-gaps may not necessarily extend through the entire thickness of the first dielectric layer 14 to enhance the electric field.

Optionally, the cross section of the semiconductor channel layer 12 in the region below the first dielectric layer 14 may have a rectangular shape, a trapezoidal shape (not shown), or a triangular shape (not shown), thereby further enhancing the electric field at the interface between the semiconductor channel layer 12 and the first dielectric layer 14.

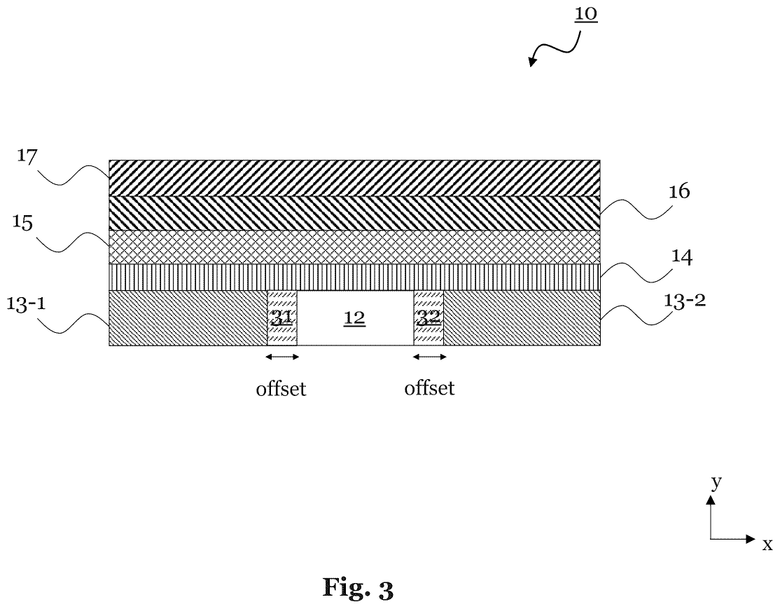

FIG. 3 schematically illustrate a transistor structure 10 according to an embodiment, which builds on the embodiment shown in FIG. 1. In particular, FIG. 3 shows a cross-sectional view of the transistor structure 10 along the x-y plane. Hereinafter, for brevity, only the differences between FIG. 3 and FIG. 1 are explained.

The transistor structure 10 according to FIG. 3 may further comprise a first spacer layer 31 arranged between the first auxiliary layer 13-1 and the semiconductor channel layer 12 along the first axis.

Additionally or alternatively, the transistor structure 10 may further comprise a second spacer layer 32 arranged between the semiconductor channel layer 12 and the second auxiliary layer 13-2 along the first axis.

Each of the first spacer layer 31 and the second spacer layer 32 may comprise, or may be formed of, a third material. The third material may have a third relative permittivity ε_{r,3} that is larger than the first relative permittivity ε_{r,1} and smaller than the second relative permittivity ε_{r,2}, that is, ε_{r,1}<ε_{r,3}<ε_{r,2}.

For example, the third material may comprise or may be SiO₂.

The enhancement of the electric field at the corners of the semiconductor channel layer 12 may be smaller compared to the embodiment according to FIG. 1 due to the presence of the first spacer layer 31 and the second spacer layer 32. Notably, since the pockets or air gaps 13-1, 13-2 have the lowest relative permittivity ε_{r,1} compared to that of the first dielectric layer 14 and the first spacer layer 31 and/or the second spacer layer 32, the field enhancement effect provided by the pockets/air gaps 13-1, 13-2 can still be obtained.

Moreover, since some existing vertical NAND flash memory devices may comprise SiO₂ spacers between channels lines to reduce crosstalk between neighboring channels, the embodiment according to FIG. 3 may provide a similar effect as the embodiment according to FIGS. 1 and 2 with the additional advantage of being compatible with existing architectures.

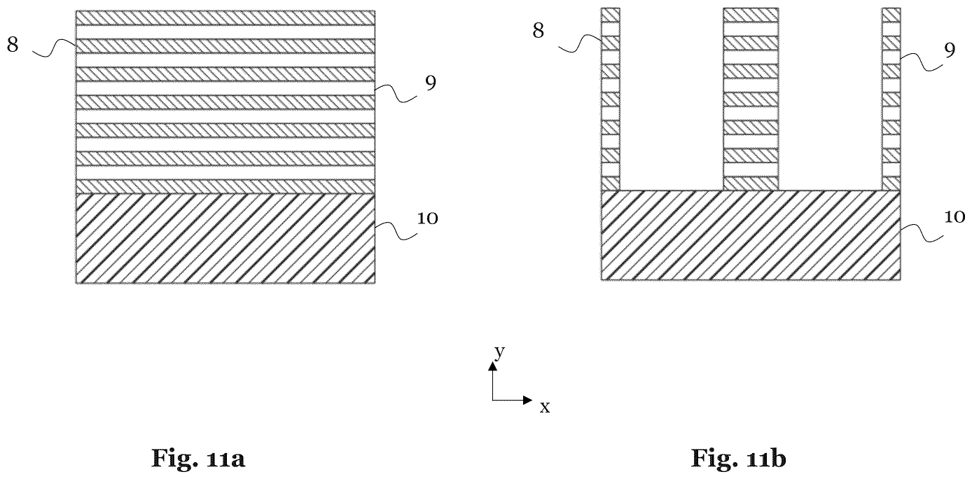

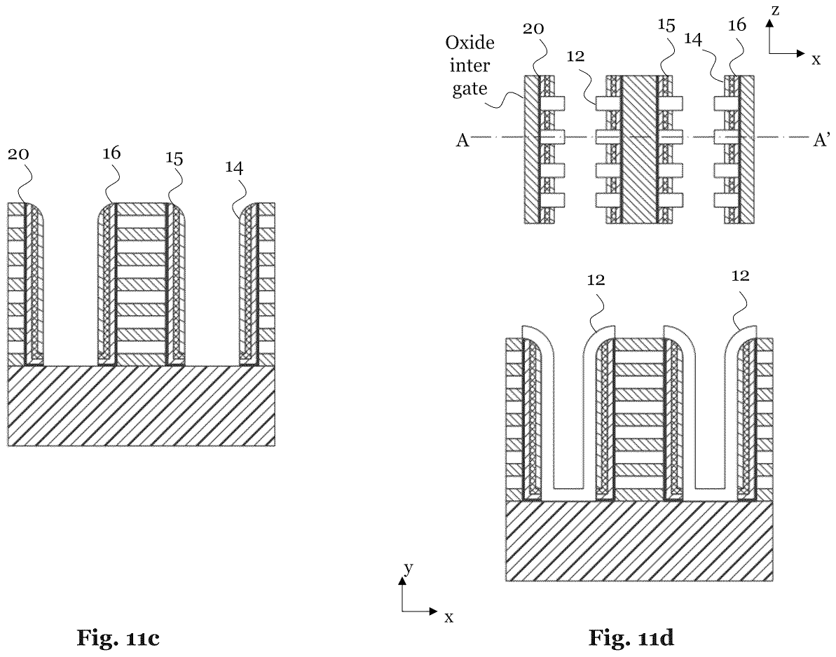

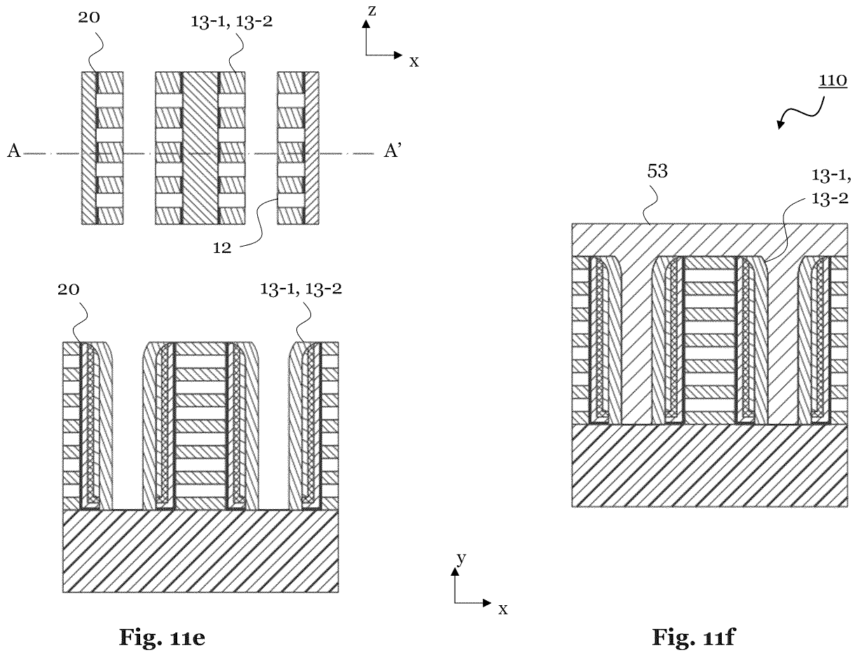

Each of the first spacer layer 31 and the second spacer layer 32 may have a lateral dimension along the first axis, for example a width or an offset. Thus, in this embodiment, the offset of the first spacer layer 31 and/or the second spacer layer 32 may be tailored in order to achieve a particular electric field enhancement, as illustrated in FIGS. 11a to 11d.

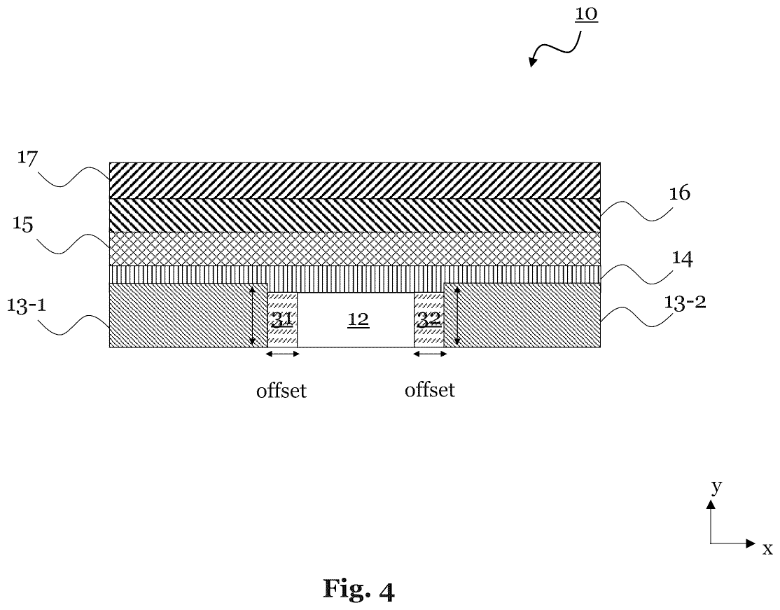

FIG. 4 schematically illustrates a transistor structure 10 according to an embodiment, which builds on the embodiment shown in FIG. 3. In particular, FIG. 4 shows a cross-sectional view of the transistor structure 10 along the x-y plane. Hereinafter, for brevity, only the differences between FIG. 4 and FIG. 3 are explained.

In the embodiment according to FIG. 4, the first auxiliary layer 13-1 may partially extend into the first dielectric layer 14 along the second axis. Additionally or alternatively, the second auxiliary layer 13-2 may partially extend into the first dielectric layer 14 along the second axis.

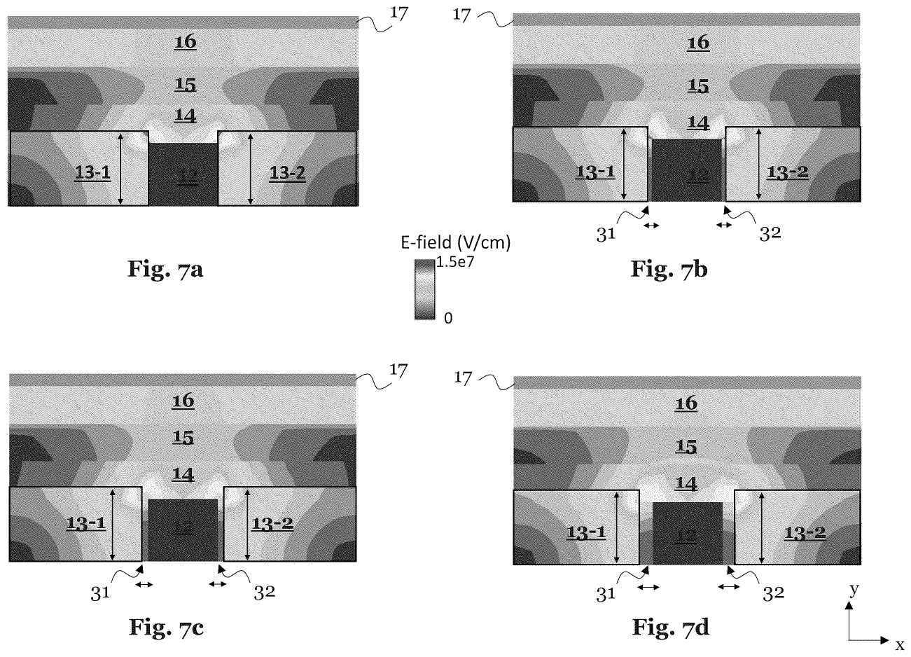

Thus, in this embodiment, the thickness (or height) of the pockets/air-gaps 13-1, 13-2 may be designed to counteract the effect of the first and second spacer layers 31, 32 so that a particular enhancement of the electric field at the corners of the semiconductor channel layer 12 can be achieved, as illustrated in FIGS. 7a to 7d, where the interplay between the extension (thickness or height) of the pockets/air-gaps 13-1, 13-2 and the width (offset) of the first and second spacer layers 31, 32 is shown.

Optionally, the cross section of the semiconductor channel layer 12 in the region below the first dielectric layer 14 may have a rectangular shape, a trapezoidal shape (not shown), or a triangular shape (not shown).

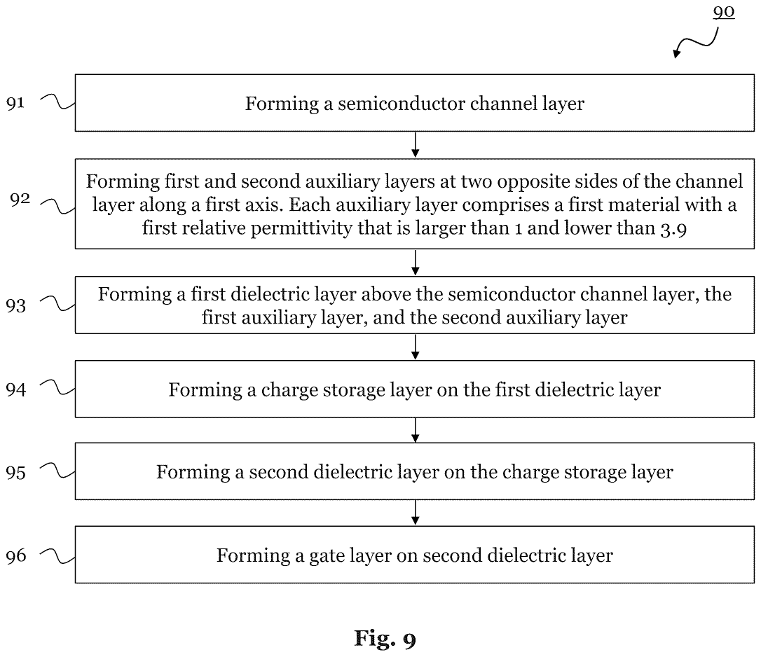

FIG. 9 is a flowchart illustrating an example method 90 for fabricating the transistor structure 10, according to an embodiment.

The method 90 may comprise a step 91 of forming a semiconductor channel layer 12.

The method 90 may further comprise a step 92 of forming a first auxiliary layer 13-1 and a second auxiliary layer 13-2 at two opposite sides of the semiconductor channel layer 12 along a first axis. Each of the first auxiliary layer 13-1 and the second auxiliary layer 13-2 may comprise a first material having a first relative permittivity being greater than 1.0 and lower than 3.9. In some embodiments, the first relative permittivity may be, for example, between 1.0 and 1.5, between 1.5 and 2.0, between 2.0 and 2.5, between 2.5 and 3.0, between 3.0 and 3.5, between 3.5 and 3.9, or a value in a range defined by any of these values.

Then, in a step 93, the method 90 may comprise forming a first dielectric layer 14 above the semiconductor channel layer 12, the first auxiliary layer 13-1 and the second auxiliary layer 13-2, along a second axis that is perpendicular to the first axis.

In a step 94, the method 90 may comprise forming a charge storage layer 15 on the first dielectric layer 14.

Further, the method 90 may comprise a step 95 of forming a second dielectric layer 16 on the charge storage.

Then, in a step 96, the method 90 may comprise forming a gate layer 17 on the second dielectric layer 16.

In an embodiment, before the step 93, the method 90 may comprise an optional step 92-2 of forming a first spacer layer 31 between the first auxiliary layer 13-1 and the semiconductor channel layer 12 along the first axis. Additionally or alternatively, the step 92-2 may comprise forming a second spacer layer 32 between the semiconductor channel layer 12 and the second auxiliary layer 13-2 along the first axis.

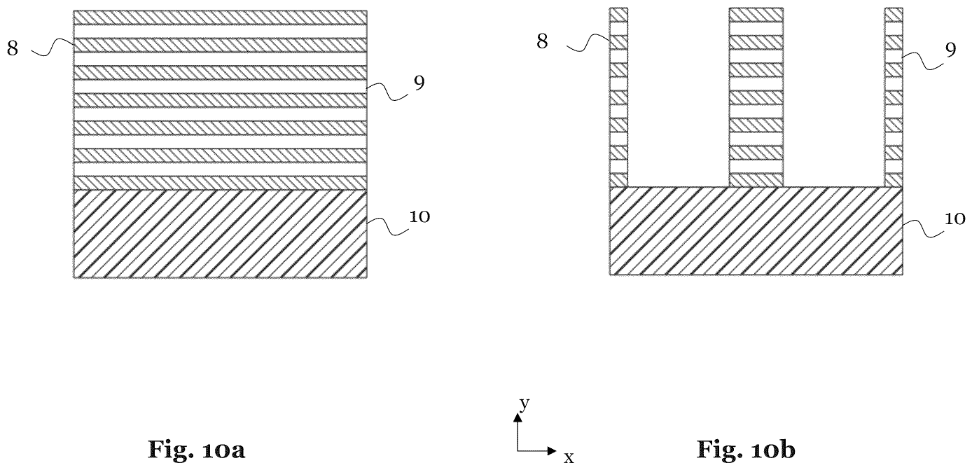

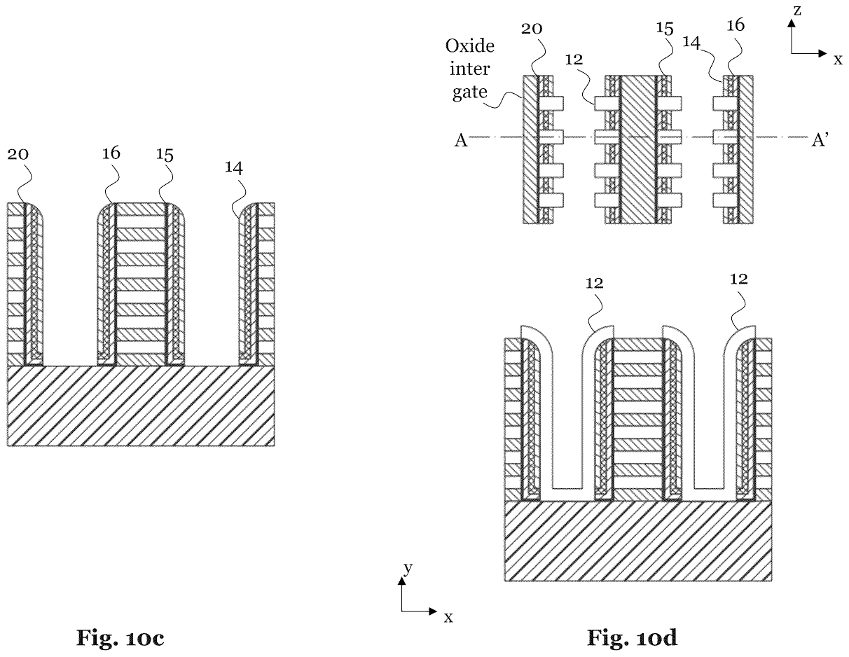

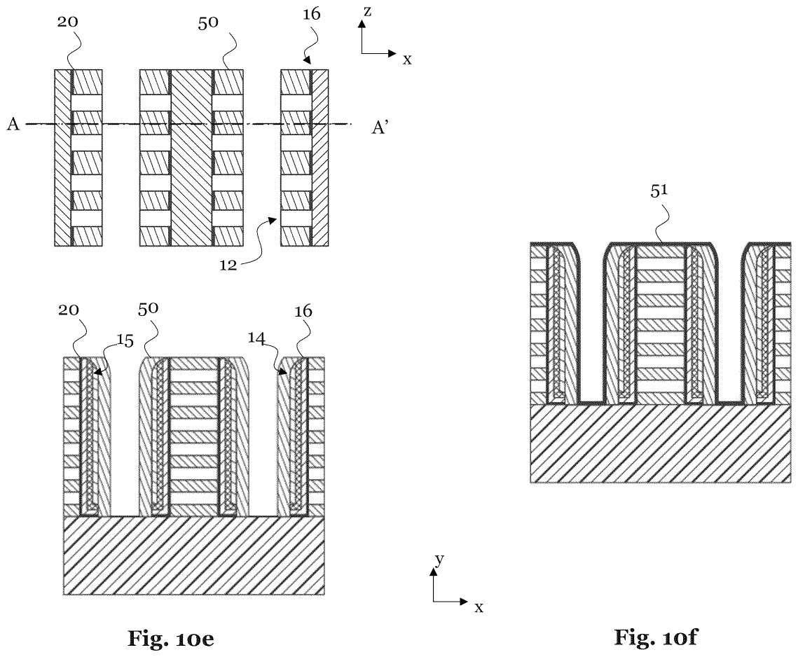

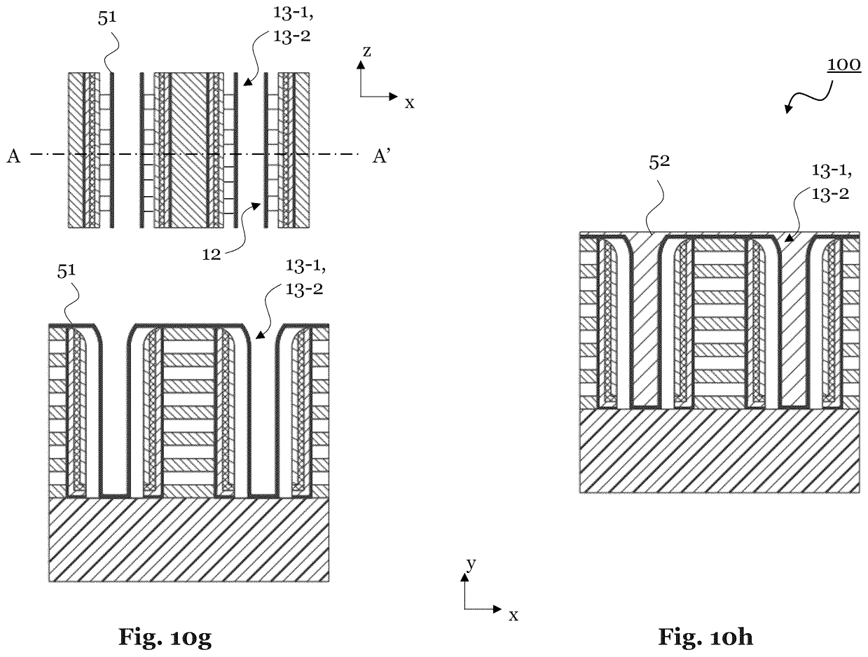

FIG. 10h schematically shows a cross section of a vertical NAND flash memory device 100 according to an embodiment. The vertical NAND flash memory device 100 may comprise one or more of the transistor structures 10 according to any one of FIGS. 1 to 5.

The vertical NAND flash memory device 100 may be a 3D NAND flash memory.

In the vertical NAND flash memory device 100 according to FIG. 10h, the first material comprised in the first auxiliary layer 13-1 and the second auxiliary layer 13-2 is air. In other words, the vertical NAND flash memory device 100 according to FIG. 10h may comprise a plurality of air gaps 13-1, 13-2.

FIGS. 10a to 10h schematically show various intermediate or final structures formed in the course of performing an example fabrication method of the vertical NAND flash memory device 100 according to an embodiment.

In a first step of the method, shown in FIG. 10a, a substrate 10 may be provided and a first layer stack may be formed on the substrate 10.

The first layer stack may comprise one or more oxide inter-gate spacing layers 8 alternating with one or more silicon nitride (SiN) layers 9, e.g., silicon mononitride layers. The SiN layers 9 may form word lines of the vertical NAND flash memory device 100. The substrate 10 may be a silicon substrate, for example a silicon wafer.

The first layer stack may be formed by alternately depositing the oxide inter-gate spacing layers 8 and the SiN layers 9 with a suitable deposition technique, for example CVD, PECVD, RPCVD, ALD or other.

In a second step of the method, shown in FIG. 10b, one or more trenches may be formed in the first layer stack, wherein each trench may completely penetrate the one or more oxide inter-gate spacing layers 8 and the one or more SiN layers 9.

Each trench may be formed with a suitable directional etching technique.

In a third step of the method, shown in FIG. 10c, a second layer stack may be formed in each trench. The second layer stack may comprise: a thin layer of a high-k liner material 20, the first dielectric layer 14 formed on the thin layer of the high-k liner material 20, the charge storage layer 15 formed on the first dielectric layer 14, and the second dielectric layer 16 arranged on the charge storage layer 15. As used herein, the term “high-k liner material” refers to a material having a relative permittivity higher than that of SiO₂, for example, greater than about 3.9.

The high-k liner material 20 may comprise, or may be, a material having a high relative permittivity compared to the relative permittivity of SiO₂.

The second layer stack may be formed by alternately depositing the thin layer of the high-k liner material 20, the first dielectric layer 14, the charge storage layer 15, and the second dielectric layer 16, each with a suitable deposition technique, for example, CVD, PECVD, RPCVD, ALD or another suitable process.

The second layer stack may also be referred to as a high-k oxide-nitride-oxide (ONO) structure.

Then, the second layer stack in each trench may be further patterned with a suitable lithography step, using a suitable lithography mask and a suitable isotropic or anisotropic wet or dry etching technique, leaving the substrate exposed.

In a fourth step of the method, shown in FIG. 10d, the semiconductor channel layer 12 may be formed on sidewalls of the recesses formed by patterning the second layer stack, and on the substrate.

The semiconductor channel layer 12 may be formed by depositing a semiconductor material with a suitable deposition technique, for example CVD, PECVD, RPCVD, ALD or another suitable process.

Further, the deposited semiconductor material can be patterned with a suitable lithography step, using a suitable lithography mask and a suitable isotropic or anisotropic wet or dry etching technique.

The upper part of FIG. 10d shows a top view of the structure formed in this step, and the lower part shows a cross-sectional view along the A-A′ line.

In a fifth step of the method, shown in FIG. 10e, a polymer layer 50 may be formed on the semiconductor channel layer 12.

The polymer layer 50 may be formed by depositing a polymer material with a suitable deposition technique, for example CVD, PECVD, ALD or another suitable process, on sidewalls of the recesses formed in the previous steps and on the substrate 10.

The polymer material can be further patterned with a suitable lithography step, using a suitable lithography mask and a suitable isotropic or anisotropic wet or dry etching technique, leaving the substrate exposed.

The upper part of FIG. 10e shows a top view of the structure formed in this step, and the lower part shows a cross-sectional view along the A-A′ line.

In a sixth step of the method, shown in FIG. 10f, an oxide liner layer 51 may be formed on the polymer layer 50 and on the substrate 10.

The oxide liner layer 51 may be formed by depositing a porous oxide material with a suitable deposition technique, for example CVD, PECVD, ALD or another suitable process, on sidewalls of the recesses formed in the previous step and on the substrate 10.

In a seventh step of the method, shown in FIG. 10g, the first auxiliary layer 13-1 and the second auxiliary layer 13-2, each comprising air, e.g., the air gaps, may be formed by using, e.g., a suitable thermal treatment and further decomposition of the polymer layer.

The thermal treatment and the decomposition of the polymer layer may not affect the oxide liner layer 51, as shown in FIG. 10g.

The upper part of FIG. 10g shows a top view of the structure formed in this step, and the lower part shows a cross-sectional view along the A-A′ line.

In an eight step of the method, shown in FIG. 10h, an oxide filling material 52 may be deposited to fill the one or more trenches formed in the previous steps, thereby forming the vertical NAND flash memory device 100.

FIG. 11f schematically shows a cross section of a vertical NAND flash memory device 110 according to an embodiment. The vertical NAND flash memory device 110 may comprise one or more of the transistor structures 10 according to any one of FIGS. 1 to 5, and can be a 3D NAND flash memory.

In the vertical NAND flash memory device 110 according to FIG. 11f, the first material comprised in the first auxiliary layer 13-1 and the second auxiliary layer 13-2 may be a porous material with the first permittivity being greater than 1.0 and smaller than 3.9, 1.0<ε_{r,1}<3.9. In some embodiments, the porous material may have the first relative permittivity between 1.0 and 1.5, between 1.5 and 2.0, between 2.0 and 2.5, between 2.5 and 3.0, between 3.0 and 3.5, between 3.5 and 3.9, or a value in a range defined by any of these values. In other words, the vertical NAND flash memory device 110 according to FIG. 11f may comprise a plurality of pockets 13-1, 13-2 comprising the first low-k material.

FIGS. 11a to 11f schematically show various intermediate or final structures formed in the course of performing an example fabrication method of the vertical NAND flash memory device 110 according to an embodiment.

In a first step, shown in FIG. 11a the method may comprise forming the substrate 10 and the first layer stack. The first step according to FIG. 11a may be the same as the first step of the method according to FIG. 10a as discussed above, and the details are not repeated here for brevity.

In a second step, shown in FIG. 11b, the method may comprise forming the one or more trenches in the first layer stack. The second step according to FIG. 11b may be the same as the second step of the method according to FIG. 10b as discussed above, and the details are not repeated here for brevity.

In a third step, shown in FIG. 11c, the method may comprise forming and subsequently patterning the second layer stack. The third step according to FIG. 11c may be the same as the third step of the method according to FIG. 10c as discussed above, and the details are not repeated here for brevity.

In a fourth step, shown in FIG. 11d, the method may comprise forming the semiconductor channel layer 12 on sidewalls of the recesses formed by patterning the second layer stack, and on the substrate 10. The fourth step according to FIG. 11d may be the same as the second step of the method according to FIG. 10d as discussed above, and the details are not repeated here for brevity.

In a fifth step of the method, shown in FIG. 11e, the first auxiliary layer 13-1 and the second auxiliary layer 13-2 may be formed on the semiconductor channel layer 12.

The first auxiliary layer 13-1 and the second auxiliary layer 13-2 may be formed by depositing the first material having the first relative permittivity, e.g., the first low-k material, with a suitable deposition technique, for example CVD, PECVD, ALD or another suitable process, on sidewalls of the recesses formed in the previous step, and on the substrate. As discussed above, the first material in this embodiment may be different from air.

Further, the first material can be patterned with a suitable lithography step, using a suitable lithography mask and a suitable isotropic or anisotropic wet or dry etching technique, leaving the substrate exposed.

Alternatively, the first auxiliary layer 13-1 and the second auxiliary layer 13-2 may be formed by performing area selective deposition (ASD) of the first material (e.g., the low-k material) on the tunnel oxide and between the neighboring channel layers 12, wherein the process is selective to the channel 12 such that the first material is substantially not deposited on the channel 12.

Thereby, the pockets 13-1, 13-2 may be formed at both sides of the channel 12.

The upper part of FIG. 11e shows a top view of the structure formed in this step, and the lower part shows a cross-sectional view along the A-A′ line.

In a sixth step of the method, shown in FIG. 11f, an oxide filling material 53 may be deposited to fill the one or more trenches formed in the previous steps, thereby forming the vertical NAND flash memory device 110.

By incorporating the pockets or air-gaps 13-1, 13-2 at both sides of each of the channels 12 and with the low permittivity relative to that of the tunnel oxide 14, the vertical NAND flash memory device 100, 110 according to the embodiments of FIGS. 10h and 11f provide the advantage of inducing charge polarization at the interface between the pockets/air-gaps 13-1, 13-2 and the tunnel oxide 14 that locally increases the electric field around the corners of the channel 12, thereby resulting in an enhanced carrier injection during programming and erase of the memory 100, 110. This improvement is reflected in a significantly improved onset and a slope of an incremental step pulse programming (ISPP) curve of the vertical NAND flash memory device 100, 110.

What is claimed is:

1. A transistor structure for a vertical NAND flash memory device, the transistor structure comprising:
a semiconductor channel layer;
a first auxiliary layer and a second auxiliary layer arranged on opposite sides of the semiconductor channel layer along a first axis, wherein each of the first auxiliary layer and the second auxiliary layer comprises a first material having a first relative permittivity greater than 1.0 and less than 3.9;
a first dielectric layer arranged above the semiconductor channel layer, the first auxiliary layer, and the second auxiliary layer, along a second axis perpendicular to the first axis;
a charge storage layer arranged on the first dielectric layer;
a second dielectric layer arranged on the charge storage layer; and
a gate layer arranged on the second dielectric layer.

2. The transistor structure according to claim 1, wherein the first auxiliary layer partially extends into the first dielectric layer along the second axis.

3. The transistor structure according to claim 1, wherein the second auxiliary layer partially extends into the first dielectric layer along the second axis.

4. The transistor structure according to claim 1, wherein the first material is or comprises air.

5. The transistor structure according to claim 1, wherein the first material comprises a porous material.

6. The transistor structure according to claim 1, wherein the first dielectric layer comprises a second material having a second relative permittivity, the second relative permittivity being greater than the first relative permittivity.

7. The transistor structure according to claim 1, wherein a cross section of the semiconductor channel layer in a region below the first dielectric layer has a rectangular, trapezoidal, or triangular shape.

8. The transistor structure according to claim 6, the transistor structure further comprising a first spacer layer arranged between the first auxiliary layer and the semiconductor channel layer along the first axis.

9. The transistor structure according to claim 8, the transistor structure further comprising a second spacer layer arranged between the semiconductor channel layer and the second auxiliary layer along the first axis.

10. The transistor structure according to claim 8, wherein the first spacer layer comprises a third material, the third material having a third relative greater than the first relative permittivity and less than the second relative permittivity.

11. The transistor structure according to claim 9, wherein the second spacer layer comprises a third material, the third material having a third relative greater than the first relative permittivity and less than the second relative permittivity.

12. The transistor structure according to claim 10, wherein the third material comprises silicon dioxide (SiO₂).

13. A vertical NAND flash memory device comprising one or more transistor structures according to claim 1.

14. The vertical NAND flash memory device according to claim 13, wherein the first dielectric layer serves as a tunnel dielectric layer.

15. The vertical NAND flash memory device according to claim 14, wherein the charge storage layer serves as a floating gate.

16. The vertical NAND flash memory device according to claim 15, wherein the second dielectric layer serves as a blocking dielectric.

17. A method of fabricating a transistor structure for a vertical NAND flash memory, the method comprising:
forming a semiconductor channel layer;
forming a first auxiliary layer and a second auxiliary layer on opposite sides of the semiconductor channel layer along a first axis, wherein the first auxiliary layer and the second auxiliary layer each comprise a first material having a first relative greater than 1.0 and less than 3.9;
forming a first dielectric layer above the semiconductor channel layer, the first auxiliary layer, and the second auxiliary layer along a second axis perpendicular to the first axis;
forming a charge storage layer on the first dielectric layer;
forming a second dielectric layer on the charge storage layer; and
forming a gate layer on the second dielectric layer.

18. The transistor structure according to claim 1, wherein the first auxiliary layer has a first thickness along the second axis, the second auxiliary layer has a second thickness along the second axis, and the semiconductor channel layer has a third thickness along the second axis, wherein the first thickness, the second thickness, and the third thickness are substantially the same.

19. The transistor structure according to claim 1, wherein the first auxiliary layer has a first thickness along the second axis, the second auxiliary layer has a second thickness along the second axis, and the semiconductor channel layer has a third thickness along the second axis, wherein the first thickness and the second thickness are substantially the same, and the third thickness is less than the first thickness and the second thickness.
